(19) United States
(12) Patent Application Publication
(10) Pub. No.: US 2003/0124790 A1
(43) Pub. Date: Jul. 3, 2003

(54) Versatile system for PMOS I/O transistor integration

(76) Inventor: PR Chidambaram, Richardson, TX (US)

Correspondence Address: TEXAS INSTRUMENTS INCORPORATED, P O BOX 655474, M/S 3999, DALLAS, TX, 75265

(21) Appl. No.: 10/171,160

(22) Filed: Jun. 13, 2002

Related U.S. Application Data
(60) Provisional application No. 60/344,632, filed on Dec. 28, 2001.

(51) Int. Cl. H01L 21/8238; H01L 21/336

(52) U.S. Cl. 438/201; 438/199

(57) ABSTRACT

A system for fabricating an integrated circuit is disclosed in which a mixed voltage device (100), having a core gate (200) and a PMOS I/O gate (400) is formed on a substrate (10). A positively doped silicate glass (35) is deposited on the mixed voltage device, and the core gate is processed. Finally, the source/drain region (50) of the high voltage PMOS I/O gate is implanted with positive ions from the positively doped silicate glass that diffuse into the substrate at the PMOS I/O gate.

This application claims priority from Provisional Application Serial No. 60/344,632, filed on Dec. 28, 2001.

### TECHNICAL FIELD OF THE INVENTION

The present invention relates in general to the field of integrated circuits and, more particularly, to formation of an input/output structure for multi-voltage devices.

### BACKGROUND OF THE INVENTION

The manufacturing cost of a given integrated circuit is dependent largely upon the chip area required to implement desired functions. The chip area is defined by the geometries and sizes of the active components disposed on the wafer substrate. Active components include gate electrodes in metal-oxide semiconductors (MOS), and diffused regions, such as MOS source and drain regions and bipolar emitters, collectors and base regions.

Lithographic patterning and etching are critical to the efficient formation of integrated circuits. Each lithographic patterning step creates the potential for device failure. During the formation of an integrated circuit core, and the subsequent formation of the I/O structures that form, e.g., the connections with packaging components, photolithographic steps have traditionally been used to separate the formation of the core of the device from the input-output (I/O) portion or portions of devices.

For mixed voltage technologies, e.g., low voltage core transistors with operating voltages of about 1.8 to 1.2 volts, and high voltage I/O transistors with operating voltages of about 3.3 to 2.5 volts, it is difficult to achieve both high reliability and high performance for both the core transistors and the I/O transistors without adding extra mask steps to independently optimize the core and the I/O transistors. The higher operating voltages of the I/O transistors make them susceptible to, e.g., hot carrier degradation. To reduce hot carrier degradation, a lightly doped drain (LDD) or drain extension may be used.

Present integrated circuit fabrication methodologies require the use of additional masking steps to separately optimize the formation of both transistor regions: core and I/O. Therefore, there is a need for reduction in the masking process that will optimize both transistors and result in both high reliability and high performance without the high cost associated with increased masking steps.

### SUMMARY OF THE INVENTION

Therefore, what is now needed is an I/O device, and method of making the same, that may be formed consistently and with reduced steps using existing process equipment, processes and workflows. A need has arisen for a simplified process for forming I/O structures for multiple voltage devices that is economical to make using existing techniques and materials.

The present invention provides a mixed voltage system for high reliability and high performance core and input-output transistors with reduced masks. An embodiment of the instant invention provides a method of making a reliable PMOS input-output transistor. The present invention provides the source/drain regions for PMOS I/O gates in a mixed voltage integrated circuit by forming a mixed voltage integrated circuit, comprising a core gate and a PMOS I/O gate on a substrate. A positively doped silicate glass is deposited on the mixed voltage integrated circuit, and the PMOS I/O gate is protected with photoresist. Next, the core gate of the mixed voltage integrated circuit is processed. Finally, the PMOS I/O gate is exposed, and the positively doped silicate glass is diffused with positive ions, from the positively doped silicate glass, that form the source/drain into the substrate about the PMOS I/O gate, without the need for an extra mask step.

### BRIEF DESCRIPTION OF THE DRAWINGS

For a more complete understanding of the features and advantages of the present invention, reference is now made to the detailed description of the invention along with the accompanying figures in which corresponding numerals in the different figures refer to corresponding parts and in which:

FIG. 1 is a cross section of a mixed voltage device according to the present invention and the deposition of positively doped silicate glass;

FIG. 2 is a cross section of the processing stage of a mixed voltage device according to the present invention;

FIG. 3 is a cross section of the processing stage of a mixed voltage device according to the present invention;

FIG. 4 is a cross section of the processing stage of a mixed voltage device according to the present invention; and

FIG. 5 is a cross section of the final source/drain implantation according to the present invention.

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The specific embodiments discussed herein are merely illustrative of specific ways to make and use the invention and are not to delimit the scope of the invention.

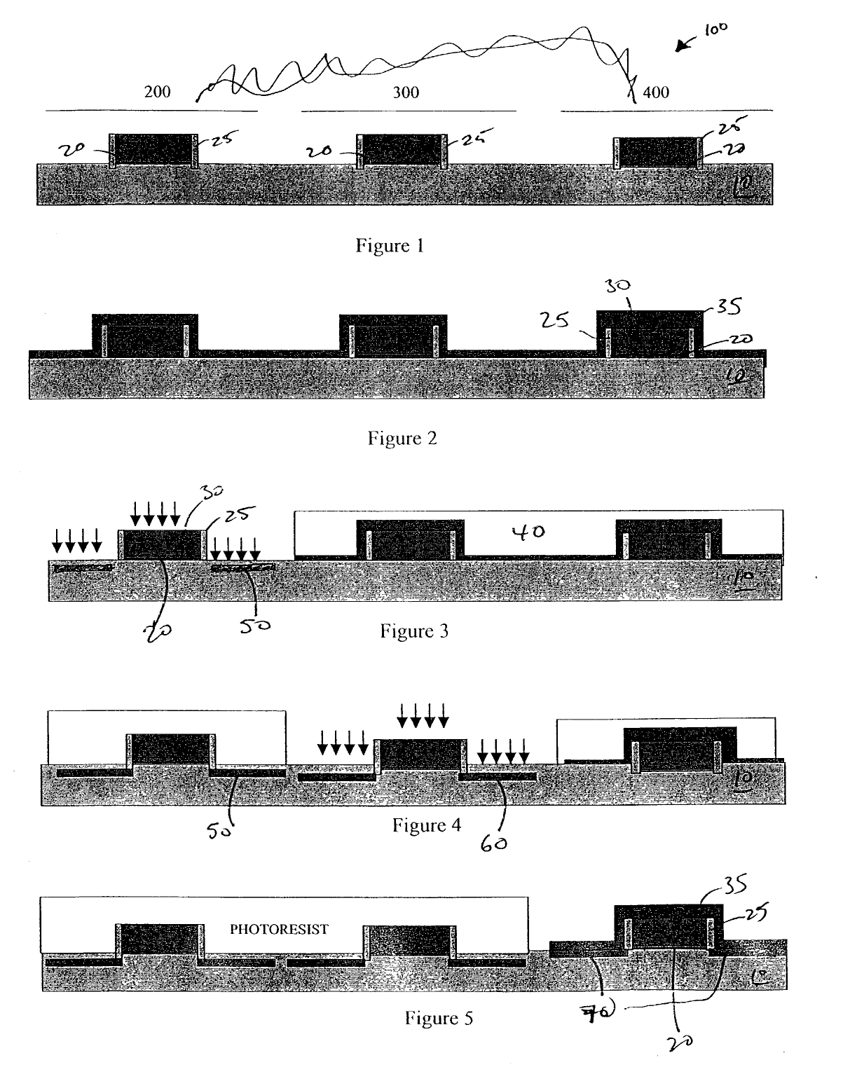

The following description of the invention relates to the mixed signal device 100 of FIG. 1. A substrate 10 is provided and a gate dielectric 20 is formed on substrate 10. The substrate 10 is preferably p-type in conductivity, but n-type substrates may also be used. Gate dielectric 20 may be made of, e.g., an oxide, thermally grown SiO₂, a nitride, an oxynitride or any combination thereof, and is generally on the order of, e.g., 1 to 10 nm thick. A layer of silicon-containing material, which may be patterned and etched to form gate structure 30, is formed on gate dielectric 20. The gate structure 30 on the gate dielectric 20 may have sidewalls 25.

Substrate 10 may be made of silicon, gallium arsenide, silicon on insulator (SOI) structures, epitaxial formations, germanium, germanium silicon, polysilicon, amorphous silicon, and/or like substrates, semi-conductive or conductive. The substrate 10 is typically made of single crystal silicon, and is usually lightly doped with boron, phosphorous or arsenic atoms.

The silicon-containing material of the gate structure 30 may be, e.g., polycrystalline silicon (“poly” or “polysilicon”), or it may be epitaxial silicon or any other semiconducting material. The substrate may also include isolation structures between the regions for forming the different gate structures 30. These isolation structures may include an oxide or some other insulator (not depicted). The purpose of an isolation structure is to isolate the active devices from one another on the substrate 10. Once formed, the substrate 10 may contain wells (not depicted) that will be of the opposite conductivity type when compared to the conductivity of the substrate.

In the embodiment of the present invention depicted in FIG. 1, the substrate 10 maybe, e.g., n-type and the well may be p-type. A core transistor region 200, an NMOS I/O transistor region 300 and a PMOS I/O transistor region 400 are fabricated on the substrate 10. The gate dielectric 20 for the I/O transistors 20 will generally be thicker than the gate dielectric 20 for the core transistors.

As shown in FIG. 2, with the gate structures 30 formed, a layer of positively doped glass 35, e.g., borosilicate glass (BSG), is deposited on the formed gate structures 30. The borosilicate glass may be doped with B, BF₂ or combinations thereof, and may be deposited by, e.g., chemical vapor deposition, sputtering or other convenient methods.

The layer of positively duped glass, (e.g., borosilicate glass) may be deposited using a low-pressure chemical-vapor deposition (LPCVD) process or a physical-vapor deposition (PVD) process, such as evaporation or sputtering. The positively duped glass may be deposited either by a conformal or a partially conformal deposition process. Generally, a partially conformal PVD or CVD process is used to deposit a thinner glass on all the surfaces and features on the substrate. The PVD processes, such as evaporation and sputtering, usually deposit material layers with partial conformality (typically 20% to 70%). The CVD process parameters may also be adjusted in order to achieve reduced deposition conformalities (e.g. 30% to 85%). A thin (200 to 1000 Angstroms) conformal glass may be formed using LPCVD or plasma enhanced chemical-vapor deposition (PECVD). This layer is then subjected to anisotropic ion etching in a suitable plasma chemistry to form, e.g., gate structures 30.

Turning to FIG. 3, a photoresist 40 is formed over the substrate 10 and the gates 30 that define the different regions for the multi-voltage devices. Using standard photolithographic techniques, the photoresist 40 is patterned and the exposed areas are etched to produce the core transistor region 200. Photoresist 40 covers the NMOS I/O transistor region 300 and the PMOS I/O transistor region 400, while permitting access to the core transistor region 200 for processing. At this stage, the positively doped glass 35 is removed from the surface of the core transistor region 200 using, e.g. an isotropic etch, or other conventional techniques. The core transistor region 200 gates are then processed using, e.g., standard pocket implants (not depicted) followed by a blanket implantation resulting in the doping profile for the core source/drain region 50 and gate 30.

In current integrated circuit technology, pocket implants refer to an implant that is used to reduce the effect of the short transistor gate length on transistor properties such as threshold voltage. The effect of the pocket implant is not limited to threshold voltage. The pocket implant for a particular transistor type usually results in a doping profile that extends beyond the source/drain extension of the transistor.

Referring to FIG. 4, a layer of photoresist 40 is formed on the substrate 10 and patterned so that the NMOS I/O transistor region 300 is exposed while the core transistor region 200 and the PMOS I/O transistor region 400 are protected. In this stage, the positively doped glass 35 layer is also removed from the surface of the gate region using, e.g., an isotropic etch. The NMOS I/O transistor region 300 source/drain 60 is then formed while the core transistor region 200 and the PMOS I/O transistor structure 400 are covered by photoresist 40. The NMOS I/O transistor region 300 may also be formed using standard blanket pocket implantation. The species of the n-type pocket implant may be, e.g., As, P, Sb or any other suitable n-type dopant.

Referring to FIG. 5, the formation of the PMOS I/O transistor region 400 is depicted. A layer of photoresist 40 is formed on the substrate 10 and patterned so that the core transistor region 200 and the NMOS I/O transistor region 300 are protected from further processing steps. The exposed PMOS I/O transistor region 400 is then processed by annealing the positively doped glass 35, which causes the migration of the positive dopant into the source/drain region 70 in the substrate 10, thereby forming the high voltage source/drain 70 of the PMOS I/O transistor region 400. The amount of migration and doping may be controlled by, e.g., adjusting the concentration of the dopant, adjusting the anneal time or the temperature. The species of the p-type LDD implant for the formation of the PMOS S/D may be made using B or BF₂ or any other suitable p-type dopant that is able to migrate from the P-doped silicate glass into the substrate 10 using, e.g., a low temperature anneal. One example for use with the invention is borosilicate glass (BSG), which may be deposited using standard deposition techniques. After completion of the implants the integrated circuit is completed using standard CMOS processing techniques. Although the species of the doping pocket implant illustrated is B, other suitable p-type dopants may be used in particular settings, as will be apparent to those of skill in the art in light of the present invention.

While this invention has been described with reference to illustrative embodiments, it is not intended that this description be construed in a limiting sense. Various modifications and combinations of the illustrative embodiments, as well as other embodiments of the invention will be apparent to persons skilled in the art upon reference to the description. It is therefore intended that the appended claims encompass any such modifications or embodiments.

What is claimed is:

1. A method of fabricating an integrated circuit, comprising the steps of:
forming a core gate and a PMOS I/O gate on a substrate;
depositing a positively doped silicate glass on the core gate and PMOS I/O gate;
protecting the PMOS I/O gate with photoresist;
processing the core gate;
exposing the PMOS I/O gate and the positively doped silicate glass; and
diffusing positive ions from the positively doped silicate glass into the substrate about the PMOS I/O gate.

2. The method of claim 1, wherein the PMOS I/O gate oxide comprises a material selected from the group consisting of: silicon dioxide, silicon oxynitride, silicon nitride, and any combination thereof.

3. The method of claim 1, wherein the PMOS I/O gate comprises a material selected from the group consisting of: doped polysilicon, undoped polysilicon, epitaxial silicon, and any combination thereof.

4. The method of claim 1, wherein the positively doped silicate glass comprises a material selected from the group consisting of: B, BF₂, Ga, In, and any combination thereof.

5. The method of claim 1, further comprising the step of implanting the substrate adjacent to the PMOS I/O gate to form a source/drain region.

6. The method of claim 1, wherein the diffusing positive ions from the positively doped silicate glass into the substrate about the PMOS I/O gate is accomplished using a low temperature anneal.

7. The method of claim 1, wherein the diffusing positive ions from the positively doped silicate glass into the substrate about the PMOS I/O gate is accomplished using a high temperature anneal.

8. The method of claim 1, wherein the diffusing positive ions from the positively doped silicate glass into the substrate about the PMOS I/O gate is accomplished using a spike high temperature anneal.

9. A method of fabricating a mixed voltage integrated circuit, comprising the steps of:
forming a core gate, a NMOS I/O gate and a PMOS I/O gate on a substrate;
depositing a positively doped silicate glass on the core gate, NMOS I/O gate, and the PMOS I/O gate;
protecting the NMOS I/O gate and the PMOS I/O gate with photoresist;
processing the core gate and the NMOS I/O gate;
exposing the PMOS I/O gate and the positively doped silicate glass; and
diffusing positive ions from the positively doped silicate glass into the substrate about the PMOS I/O gate by anneal.

10. The method of claim 9, wherein the PMOS I/O gate oxide comprises a material selected from the group consisting of: silicon dioxide, silicon oxynitride, silicon nitride, and any combination thereof.

11. The method of claim 9, wherein the PMOS I/O gate comprises a material selected from the group consisting of: doped polysilicon, undoped polysilicon, epitaxial silicon, and any combination thereof.

12. The method of claim 9, wherein the positively doped silicate glass comprises a material selected from the group consisting of: B, BF₂ and any combination thereof.

13. The method of claim 9, wherein the diffusing positive ions from the positively doped silicate glass into the substrate about the PMOS I/O gate is accomplished using a low temperature anneal.

14. The method of claim 9, wherein the diffusing positive ions from the positively doped silicate glass into the substrate about the PMOS I/O gate is accomplished using a high temperature anneal.

15. The method of claim 9, wherein the diffusing positive ions from the positively doped silicate glass into the substrate about the PMOS I/O gate is accomplished using a spike anneal.

16. A method of fabricating a semiconductor device, comprising the steps of:
forming a core gate, a NMOS I/O gate and a PMOS I/O gate on a substrate;
depositing a positively doped silicate glass on the core gate, NMOS I/O gate, and the PMOS I/O gate;
protecting the PMOS I/O gate with photoresist;
processing the core gate and the NMOS I/O gate; and
implanting the source/drain regions of the PMOS I/O gate with positive ions from the positively doped silicate glass.

17. The method of claim 16, wherein the positively doped silicate glass is a borosilicate glass.

18. The method of claim 16, wherein the diffusing positive ions from the positively doped silicate glass into the substrate about the PMOS I/O gate is accomplished using a low temperature anneal.

19. The method of claim 16, wherein the diffusing positive ions from the positively doped silicate glass into the substrate about the PMOS I/O gate is accomplished using a high temperature anneal.

20. The method of claim 16, wherein the diffusing positive ions from the positively doped silicate glass into the substrate about the PMOS I/O gate is accomplished using a spike high temperature anneal.
